(19) United States
(12) Patent Application Publication
(10) Pub. No.: US 2023/0290786 A1
(43) Pub. Date: Sep. 14, 2023

(54) MOS TRANSISTOR ON SOI STRUCTURE

(71) Applicants: STMicroelectronics (Crolles 2) SAS, Crolles (FR); STMicroelectronics SA, Montrouge (FR)

(72) Inventors: Sebastien CREMER, Sassenabe (FR); Frederic MONSIEUR, Pontcharra (FR); Alain FLEURY, Barberaz (FR); Sebastien HAENDLER, Barraux (FR)

(73) Assignees: STMicroelectronics (Crolles 2) SAS, Crolles (FR); STMicroelectronics SA, Montrouge (FR)

(21) Appl. No.: 18/118,391

(22) Filed: Mar. 7, 2023

(30) Foreign Application Priority Data
Mar. 11, 2022 (FR) 2202143

(51) Int. Cl. H01L 27/12; H01L 21/762; H01L 23/48; H01L 23/528; H01L 23/532

(52) U.S. Cl. CPC H01L 27/1203; H01L 21/76264; H01L 23/481; H01L 23/528; H01L 23/53257

(57) ABSTRACT

A device includes an active semiconductor layer on top of and in contact with an insulating layer which overlies a semiconductor substrate. A transistor for the device includes a source region, a drain region, and a body region arranged in the active semiconductor layer. The body region of the transistor is electrically coupled to the semiconductor substrate using a conductive via that crosses through the insulating layer.

### PRIORITY CLAIM

This application claims the priority benefit of French Application for Patent No. 2202143, filed on Mar. 11, 2022, the content of which is hereby incorporated by reference in its entirety to the maximum extent allowable by law.

### TECHNICAL FIELD

The present disclosure generally concerns electronic components and, more particularly, Metal Oxide Semiconductor (MOS) transistors. It more particularly aims at a MOS transistor formed inside and on top of a Semiconductor On Insulator (SOI) structure.

### BACKGROUND

Various embodiments of Metal Oxide Semiconductor (MOS) transistors integrated inside and on top of a Semiconductor On Insulator (SOI) structure have already been provided. MOS transistors on an SOI structure have various advantages, among which a high integration density and a high electric performance.

It would be desirable to at least partly overcome certain disadvantages of known embodiments of MOS transistors on an SOI structure.

### SUMMARY

In an embodiment, a device comprises an active semiconductor layer on top of and in contact with an insulating layer, the device comprising at least one transistor comprising a source region, a drain region, and a body region arranged in the active layer, the body region being coupled to a conductive via crossing the insulating layer.

According to an embodiment, the insulating layer is arranged on top of and in contact with a semiconductor substrate, the conductive via being configured to electrically connect the body region to the semiconductor substrate.

According to an embodiment, the device comprises a body contact pad, connected to the body region, the contact pad being connected to the conductive via by a metal track of an interconnection network of the device.

According to an embodiment, said metal track is entirely arranged in a lowest metal track level of the interconnection network.

According to an embodiment, the conductive via is laterally insulated from the active layer.

According to an embodiment, the conductive via is made of a metallic material, for example, made of tungsten.

According to an embodiment, the transistor comprises a stack of a gate insulator and of a conductive gate topping the body region between the source and drain regions.

According to an embodiment, the transistor is a partially depleted semiconductor on insulator (PDSOI) transistor.

According to an embodiment, the device comprises a plurality of transistors arranged inside and on top of the active layer, the device comprising, for each transistor, a specific conductive via per transistor, connected to the body region of the transistor and crossing the insulating layer.

According to an embodiment, the device comprises a plurality of transistors formed inside and on top of the active layer, the conductive via being connected to body regions of a plurality of transistors of the device.

Another embodiment provides a method of manufacturing a device comprising an active semiconductor layer on top of and in contact with an insulating layer, the device comprising a transistor comprising a source region, a drain region, and a body region formed in the active layer, the method comprising forming a conductive via connected to the body region and crossing the insulating layer.

According to an embodiment, the body contact pad and the conductive via are simultaneously formed during a same metal deposition step.

According to an embodiment, the transistor is surrounded with an insulating trench, the conductive via being formed in the insulating trench.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1A shows in a partial simplified top view an example of a device comprising a Metal Oxide Semiconductor (MOS) transistors on a Semiconductor On Insulator (SOI) structure;

FIG. 1B shows a first cross-section view of the device of FIG. 1A, along cross-section plane BB of FIG. 1A;

FIG. 1C shows a second cross-section view of the device of FIG. 1A, along cross-section plane CC of FIG. 1A;

FIG. 1D shows a third cross-section view of the device of FIG. 1A, along cross-section plane DD of FIG. 1A;

FIG. 2A shows in a partial simplified top view an example of a device comprising a MOS transistor on an SOI structure according to an embodiment; and

FIG. 2B shows in a cross-section view the device illustrated in FIG. 2A.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the methods of manufacturing the described MOS transistors have not been detailed. Further, the various possible applications of the described MOS transistors have not been detailed.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred unless specified otherwise to the orientation of the cross-section views of the drawings.

Unless specified otherwise, the expressions “around”, “approximately”, “substantially” and “in the order of” signify within 10%, and preferably within 5%.

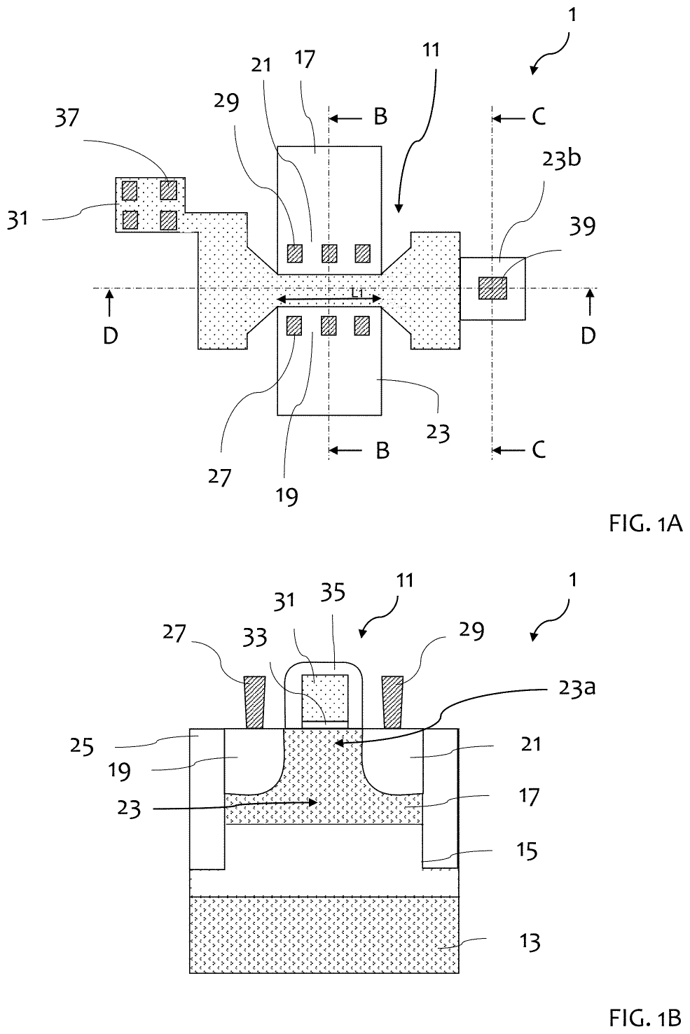

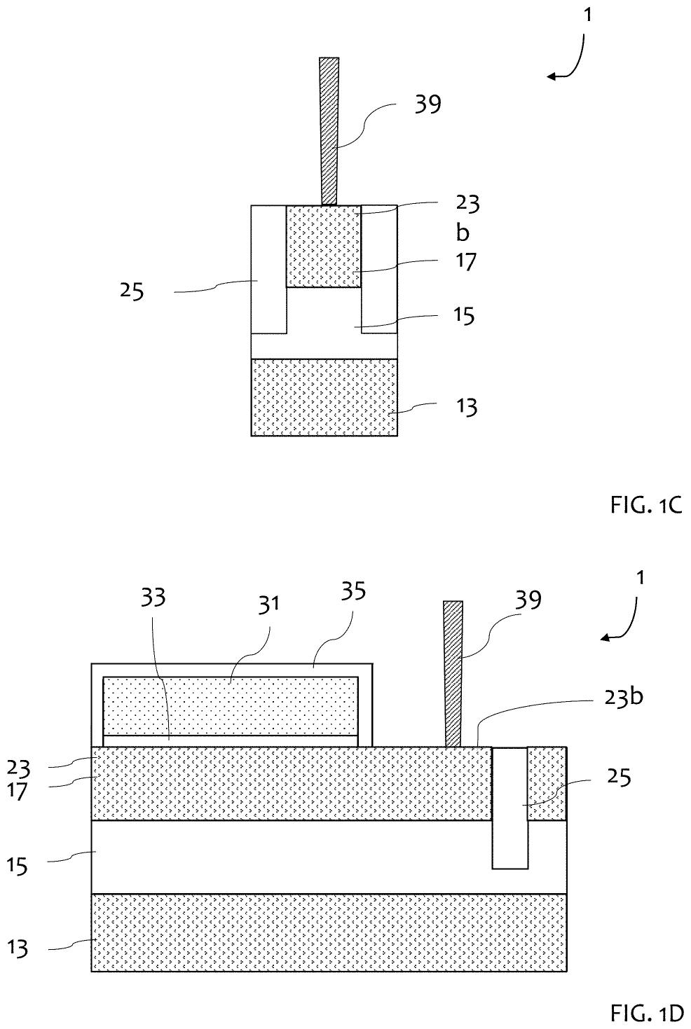

FIG. 1A shows, in a partial simplified top view, an example of a device 1 comprising a Metal Oxide Semiconductor (MOS) transistor 11.

FIG. 1B shows a first cross-section view of the device 1 of FIG. 1A, FIG. 1B being a view along cross-section plane BB of FIG. 1A.

FIG. 1C shows a second cross-section view of the device 1 of FIG. 1A, FIG. 1C being a view along cross-section plane CC of FIG. 1A.

FIG. 1D shows a third cross-section view of the device 1 of FIG. 1A, FIG. 1D being a view along cross-section plane DD of FIG. 1A.

Transistor 11 is formed inside and on top of a Semiconductor On Insulator (SOI) structure comprising a support substrate 13 made of a semiconductor material, for example, of silicon, topped with a buried insulating layer 15, for example, made of silicon dioxide (SiO₂), itself topped with an active semiconductor layer 17, for example made of silicon, for example, of single-crystal silicon.

As an example, substrate 13 has a thickness in the range from 200 μm to 800 μm, for example, from 500 μm to 800 μm, for example, in the order of 775 μm. As an example, substrate 13 is a strongly resistive substrate, for example, having a resistivity in the range from 1 kΩ·cm to 10 kΩ·cm, for example from 2 kΩ·cm to 8 kΩ·cm. Substrate 13 is, for example, P-type doped. As an example, substrate 13 is doped with boron atoms. As an example, the doping level of substrate 13 is in the range from 10¹² at/cm³ to 10¹³ at/cm³.

Buried insulating layer 15 has, for example, a thickness in the range from 100 nm to 400 nm, for example, from 100 nm to 250 nm, for example in the order of 200 nm.

Active semiconductor layer 17 has, for example, a thickness in the range from 30 nm to 500 nm, for example, from 50 nm to 200 nm, for example, in the order of 75 nm.

As an example, buried insulating layer 15 is formed on top of and in contact with semiconductor substrate 13 so that the lower surface of buried insulating layer 15 is in contact with the upper surface of semiconductor substrate 13. Active semiconductor layer 17 is, for example, formed on top of and in contact with buried insulating layer 15 so that the lower surface of active semiconductor layer 17 is in contact with the upper surface of buried insulating layer 15.

In FIGS. 1A, 1B, 1C, and 1D, a single transistor 11 has been shown. However, in practice, device 1 may comprise a plurality of transistors 11, for example, identical or similar, integrated inside and on top of the SOI structure.

Transistor 11 comprises a source region 19 and a drain region 21 formed in active semiconductor layer 17. Source and drain regions 19 and 21 are laterally separated from each other by a body region 23. An upper portion 23a of body region 23 forms the channel-forming region of transistor 11. As an example, source, drain, and body regions 19, 21 and 23 are flush with the upper surface of active semiconductor layer 17.

Transistor 11 is, for example, a P-channel MOS transistor (PMOS), that is, a transistor having its source and drain regions 19 and 21 P-type doped, for example, doped with boron atoms, while body region 23 is N-type doped, for example, doped with arsenic or phosphorus atoms. The described embodiments are however not limited to this specific case and may also apply to N-channel MOS transistors (NMOS). As an example, transistor 11 is a Partially Depleted Semiconductor On Insulator (PDSOI) transistor, that is, a transistor where, in the absence of a biasing, the body region is partially depleted (by contrast with a Fully Depleted Semiconductor On Insulator (FDSOI) transistors where, in the absence of a biasing, the body region is fully depleted).

Transistor 11 comprises one or a plurality of contact pads 27 topping source region 19 and electrically connected to source region 19, and one or a plurality of contact pads 29 topping drain region 21 and electrically connected to drain region 21. In the shown example, source contact pads 27 are in contact, by their lower surfaces, with the upper surface of source region 19 and drain contact pads 29 are in contact, by their lower surfaces, with the upper surface of drain region 21. Contact pads 27, 29 allow the electric contact between the source and drain regions 19 and 21 of transistor 11 and of other components via an interconnection network, not shown in FIGS. 1A, 1B, 1C, and 1D. In FIG. 1A, three contact pads 27 and three contact pads 29 have been shown, in practice, the number of contact pads of each type may be different from three. Contact pads 27, 29 are, for example, made of a metallic material, for example, of tungsten. As an example, source region 19 and drain region 21 are locally more heavily doped in contact with pads 27 and 29 to optimize the electric contact between regions 19, 21 and, respectively, contact pads 27 and 29.

Source and drain regions 19 and 21 extend, for example, orthogonally to the cross-section plane of FIG. 1B, along the cross-section plane DD of FIG. 1A across a first width L1.

Transistor 11 further comprises a conductive gate 31 located above channel-forming region 23a, facing channel-forming region 23a. Gate 31 is separated from channel-forming region 23a by an insulating layer 33 referred to in the art as a gate insulator. As an example, the gate insulator is made of silicon dioxide (SiO₂) and has, for example, a thickness in the range from 1 nm to 10 nm, for example, in the order of 5 nm. Gate insulator 33 is, for example, in contact, by its lower surface, with the upper surface of channel-forming region 23a, and, by its upper surface, with the lower surface of conductive gate 31. Gate 31 is, for example, covered, on its upper surface side, with a passivation insulating layer 35, for example, made of silicon dioxide. Insulating spacers may further coat the sides of gate 31 and the sides of gate insulator 33. The insulating spacers are, for example, made of silicon nitride (Si₃N₄) and/or of silicon dioxide (SiO₂). Gate 31 is, for example, made of doped polysilicon.

In the shown example, gate 31, gate insulator 33, and passivation layer 35 laterally extend beyond channel-forming region 23a. As an example, gate 31 is connected to one or other components via contact pads 37 also called gate contacts, and of an interconnection network, not shown. As an example, gate contacts 37 are offset not to be in front of channel-forming region 23a. In FIG. 1A, four gate contacts 37 have been shown. However, in practice, the number of gate contacts 37 may be different from four. As an example, gate contacts 37 are metallic, for example made of the same material as source and drain contact pads 27 and 29, for example, of tungsten. In the shown example, gate contact pads 37 are in contact, by their lower surfaces, with the upper surface of gate 31.

In this example, body region 23 laterally extends, beyond source and drain regions 19 and 21, in a body contacting region 23b flush with the upper surface level of active layer 17. Body contacting region 23b is not covered with gate 31. The transistor 11 of FIGS. 1A, 1B, 1C, and 1D comprises, in contact with body contacting region 23b, one or a plurality of contact pads 39 called body contact pads. In the example of FIGS. 1A, 1B, 1C, and 1D, transistor 11 comprises a single body contact pad 39. Body contact pad 39 is, for example, on top of and in contact, mechanically and electrically, with body contacting region 23b. As an example, body contacting region 23b is more heavily doped locally in the vicinity of contact pad 39 to optimize the electric contact between region 23 and contact pad 39. Contact pad 39 allows the electric contact between the body region 23 of transistor 11 and other components via an interconnection network not shown in FIGS. 1A, 1B, 1C, and 1D.

Contact pad 39 is preferably made of a metallic material, for example, identical to the material of contact pads 27, 29. Contact pad 39 is, for example, made of tungsten.

In this example, transistor 11 is laterally surrounded with an insulating trench 25, for example, of Shallow Trench Isolation (STI) type. Insulating trench 25 thus forms a ring around transistor 11. Insulating trench 25 extends, for example, vertically, from the upper surface of active semiconductor layer 17, through the entire thickness of active semiconductor layer 17 to reach buried insulating layer 15. In the shown example, insulating trench 25 emerges into buried insulating layer 15. As a variant (not shown), insulating trench 25 may entirely cross buried insulating layer 15 and all or part of the thickness of substrate 13. As an example, source and drain regions 19 and 21 are laterally in contact with a side of trench 25. Insulating trench 25 enables to electrically insulate transistor 11 from other components (not shown in the drawing) of the device.

Transistor 11 is, for example, covered with an interconnection network, not shown in FIGS. 1A, 1B, 1C, and 1D, enabling to connect transistor 11, by its contact pads 27, 29, 37, and 39, to other components. The interconnection network comprises, for example, a plurality of stacked metallization levels, separated two by two by insulating levels, themselves crossed by metal vias.

The forming of the interconnection network may comprise steps of plasma etching and chemical-mechanical planarization likely to generate parasitic electric charges which are likely to be trapped at the interfaces between body region 23 and insulating layers 15 and 25. More particularly, the plasmas enabling to perform the etchings are generated from significant electric voltages. The etch method is thus implemented in significant electric field conditions, which is likely to cause the introduction of parasitic charges into body region 23. Further, chemical-mechanical planarization methods may generate parasitic charges by mechanisms of electro-friction type. The accumulation of these parasitic charges undesirably modifies the electric properties of transistor 11. This issue of parasitic charge injection at the interfaces with layers 15 and/or 25 is particularly raised on forming of the upper metallization level(s) of the interconnection network, generally relatively thick, for example having a thickness in the range from 1 μm to 10 μm, for example, in the order of from 3 μm to 6 μm.

According to an aspect of an embodiment, it is provided to form, before the forming of the upper metallization levels of the interconnection network of the device, a conduction path between the body region 23 of transistor 11 and the semiconductor substrate 13 of the SOI structure, to create an evacuation path for parasitic charges and avoid their trapping at the interfaces between layers 15 and 25 delimiting body region 23.

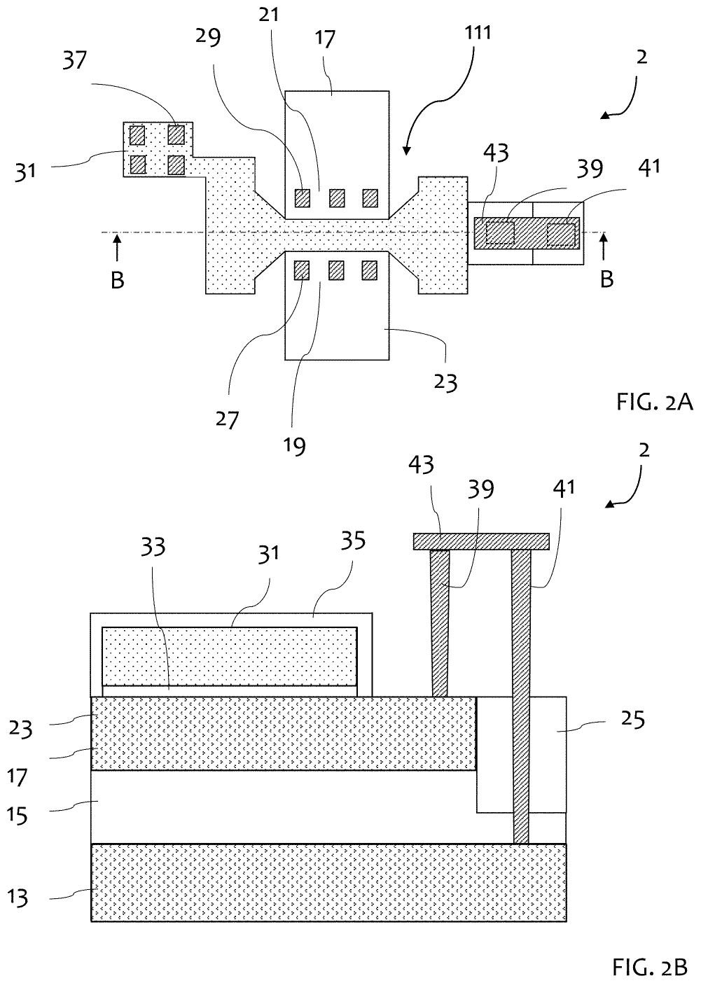

FIG. 2A shows in a partial simplified top view an example of a device 2 comprising a MOS transistor 111 according to an embodiment.

FIG. 2B shows a cross-section view of the device 2 of FIG. 2A, FIG. 2B being a cross-section view along cross-section plane BB of FIG. 2A.

The device 2 of FIGS. 2A and 2B comprises elements common with the device 1 of FIGS. 1A, 1B, 1C, and 1D. For example, transistor 111 is similar to the transistor 11 illustrated in FIGS. 1A, 1B, 1C, and 1D. For simplification, these elements will not be detailed again hereafter.

The device 2 of FIGS. 2A and 2B differs from the device 1 of FIGS. 1A, 1B, 1C, and 1D essentially in that, in the embodiment of FIGS. 2A and 2B, device 2 comprises a conductive via 41 or Via Through BOX (VTB) vertically extending through active layer 17 (more particularly, in the shown example, through an insulating layer 25 crossing active layer 17) and buried insulating layer 15 (referred to in the art as the buried oxide (BOX) layer) and emerging on top of and in contact with the upper surface of semiconductor substrate 13.

In the embodiment illustrated in FIGS. 2A and 2B, the body region 23 of transistor 11 is coupled, preferably connected, to semiconductor substrate 13 by conductive via 41. More particularly, in this example, body region 23 and semiconductor substrate 13 are coupled, preferably connected, electrically, via contact pad 39 and conductive via 41. Contact pad 39 and conductive via 41 are coupled, preferably connected, to each other, for example, directly, by a metal track 43, for example, made of copper. As an example, metal track 43 is in contact, mechanically and electrically, by its lower surface, with the upper surface of body contact pad 39 and with the upper surface of conductive via 41. Metal track 43 is, for example, a track of first metallization level M1 (corresponding to the lowest level) of the interconnection network formed on the upper surface side of the device.

Conductive via 41 is, for example, laterally insulated from active layer 17. As an example, conductive via 41 is formed in front of a portion of the SOI structure where active layer 17 has previously been removed and replaced with a dielectric material, for example, silicon dioxide (for example at the same time as insulating trenches 25 are being formed). As an example, conductive via 41 has a width greater than the width of contact pad 39. Conductive via 41 has, for example, a width in the range from 10 nm to 300 nm, for example, in the range from 50 nm to 200 nm, for example, in the order of 150 nm. Conductive via 41 is, for example, made of a metallic material, for example, identical to the material of contact pads 27, 29, 37, and/or 39, for example, made of tungsten.

Conductive via 41 is, for example, located in the vicinity of body contact pad 39.

As an example, conductive via 41 is formed in the STI insulating region 25 (as illustrated in FIGS. 2A and 2B) laterally delimiting transistor 111.

While a plurality of devices 2 are generally formed at the same time on a same semiconductor wafer, conductive vias 41 may be shared. That is, a conductive via 41 may be common to a plurality of transistors 111, for example, close to one another. In other words, a same conductive via 41 may allow the evacuation of charges accumulated inside and around of a plurality of transistors 111, for example, close to one another. In this embodiment, the body contact pads 39 of said transistors are electrically connected to one another, for example by metal tracks of the lower level(s) of the interconnection network. As a variant, the device may comprise a specific conductive via 41 per transistor.

Conductive via 41 is, for example, formed between a step of forming of a pre-metal dielectric (not detailed in the drawings) on the upper surface of active layer 17 and of gate 31 and steps of forming of the metallization levels of the interconnection of the device. As an example, the forming of conductive via 41 comprises a step of forming of an opening through insulating trench 25. As a variant, the forming of conductive via 41 comprises a step of forming of an opening through the pre-metal dielectric, active layer 17, and possibly buried insulating layer 15. The opening forming step is followed by a step of filling of the opening with the material of conductive via 41.

The forming of body contact pad 39 comprises, for example, a step of forming of an opening through the pre-metal dielectric, followed by a step of filling of the opening with the material of pad 39.

The opening of body contact pad 39 and the opening of conductive via 41 are, for example, successively performed during distinct photolithography steps. The opening of conductive via 41 is, for example, performed before the opening of contact pad 39. The filling of conductive via 41 and the filling of contact pad 39 with a conductive material are, for example, simultaneously performed after the opening forming steps, in one and the same metal deposition step followed, for example, by a chemical-mechanical planarization step.

Conductive track 43 may then be formed on top of and in contact with the upper surface of via 41 and of contact pad 39.

At this stage of the method, the body region 23 of transistor 111 is electrically connected to semiconductor substrate 13 by means of via 41. The upper metallization levels of the interconnection stack can then be formed.

An advantage of the described embodiment is that conductive via 41 enables to evacuate the generated parasitic charges, in the body region 23 of the transistor, during steps of manufacturing of the upper metallization levels of the interconnection network of the device. Conductive via 41 further allows the evacuation of charges created during other steps of the manufacturing method such as steps of sawing, grinding, etc. This enables to very significantly limit the trapping of parasitic charges at the interfaces between the body region 23 of transistor 111 and insulating layers 15 and/or 25.

In practice, during the device manufacturing method, substrate 13 may be electrically connected to a reference potential, for example, the ground, or in contact with a conductive metal support forming a ground plane.

Another advantage of the described embodiment is that conductive via 41 may be formed outside of the active portion of the transistor, the size of a transistor is thus not increased. Further, the manufacturing of conductive via 41 is compatible with usual transistor manufacturing methods.

Various embodiments and variants have been described. Those skilled in the art will understand that certain features of these various embodiments and variants may be combined, and other variants will occur to those skilled in the art. In particular, the described embodiments are not limited to the examples of materials and of dimensions mentioned in the present disclosure.

Finally, the practical implementation of the described embodiments and variations is within the abilities of those skilled in the art based on the functional indications given hereabove.

1. A device, comprising:
a semiconductor substrate;
an insulating layer on top of and in contact with the semiconductor substrate;
an active semiconductor layer on top of and in contact with the insulating layer;
a transistor comprising a source region, a drain region, and a body region arranged in the active semiconductor layer; and
a conductive via configured to electrically connect the body region to the semiconductor substrate;
wherein said conductive via crosses through the insulating layer.

2. The device according to claim 1, further comprising a body contact pad connected to the body region, wherein the body contact pad is connected to the conductive via by a metal track of an interconnection network of the device.

3. The device according to claim 2, wherein said metal track is entirely arranged in a lowest metal track level of the interconnection network.

4. The device according to claim 1, wherein the conductive via is laterally insulated from the active layer.

5. The device according to claim 4, further comprising a shallow trench isolation surrounding the transistor, and wherein the conductive via passes through the shallow trench isolation.

6. The device according to claim 1, wherein the conductive via is made of a metallic material.

7. The device according to claim 6, wherein the metallic material is tungsten.

8. The device according to claim 1, wherein the transistor comprises a stack of a gate insulator and a conductive gate topping the body region between the source and drain regions.

9. The device according to claim 1, wherein the active semiconductor layer is partially depleted.

10. A device, comprising:
a semiconductor substrate;
an insulating layer on top of and in contact with the semiconductor substrate;
an active semiconductor layer on top of and in contact with the insulating layer;
a plurality of transistors, wherein each transistor comprises a source region, a drain region, and a body region arranged in the active semiconductor layer; and
a conductive via configured to electrically connect the body region of at least one of the plurality of transistors to the semiconductor substrate;
wherein said conductive via crosses through the insulating layer.

11. The device according to claim 10, wherein said conductive via is provided for connecting the body region of each of the plurality of transistors to the semiconductor substrate.

12. The device according to claim 10, wherein said conductive via is electrically connected to the body regions of multiple ones of said plurality of transistors.

13. The device according to claim 10, wherein the conductive via is laterally insulated from the active layer.

14. The device according to claim 13, further comprising a shallow trench isolation surrounding one or more of the plurality of transistors, and wherein the conductive via passes through the shallow trench isolation.

15. The device according to claim 10, wherein the active semiconductor layer is partially depleted.

16. A method of manufacturing a device in a semiconductor on insulator substrate including a semiconductor substrate, an insulating layer on top of and in contact with the semiconductor substrate, and an active semiconductor layer on top of and in contact with the insulating layer, the method comprising:
forming a transistor supported by said semiconductor on insulator substrate, wherein the transistor includes a source region, a drain region, and a body region in the active semiconductor layer; and
forming a conductive via to electrically connect the body region of the transistor to the semiconductor substrate;
wherein forming the conductive via comprises passing the conductive via to cross through the insulating layer of the semiconductor on insulator substrate.

17. The method according to claim 16, wherein the transistor further includes a body contact pad that is connected to the body region, and further comprising connecting the body contact pad to the conductive via by a metal track of an interconnection network.

18. The method according to claim 17, wherein the body contact pad and the conductive via are simultaneously formed during a same metal deposition step.

19. The method according to claim 16, further comprising:
forming a shallow trench isolation surrounding the transistor; and
wherein forming the conductive via comprises extending the conductive via through the shallow trench isolation.
